(19) United States
(12) Patent Application Publication
(10) Pub. No.: US 2005/0287296 A1
(43) Pub. Date: Dec. 29, 2005

(54) Method and apparatus for dispersion strengthened bond coats for thermal barrier coatings

(76) Inventors: Haydn N. G. Wadley, Keswick, VA (US); David J. Wortman, Hamilton, OH (US)

Correspondence Address: UNIVERSITY OF VIRGINIA PATENT FOUNDATION, 250 WEST MAIN STREET, SUITE 300, CHARLOTTESVILLE, VA, 22902, US

(21) Appl. No.: 10/522,076

(22) PCT Filed: Jul. 24, 2003
(86) PCT No.: PCT/US03/23111

§ 371 Date: Jan. 21, 2005

Related U.S. Application Data
(60) Provisional application No. 60/398,384, filed on Jul. 25, 2002.

(51) Int. Cl. C23C 16/00

(52) U.S. Cl. 427/248.1; 118/723 VE

(57) ABSTRACT

A directed vapor deposition (DVD) method and system for applying at least one bond coating on at least one substrate for thermal barrier coating systems. The method and system provides for alloy strengthening in high temperature metallic alloys that can be melt or solid state processed to materials that one applies by vapor deposition. The creep strengthened coating contains nanoscopic particles of oxides, nitrides, borides, carbides, and other materials which are formed by reactive codeposition. An approach for reactive codeposition is plasma assisted directed vapor deposition. Accordingly, the resultant structure may be utilized for, but not limited thereto, high temperature coatings, e.g. for protecting rocket or power turbines, or diesel engine components. The resultant structure is has a greatly extended lifetime attributed in part to the elimination of coating spallation by the “rumpling” mechanism.

### RELATED APPLICATIONS

The present invention claims priority from U.S. Provisional Application Ser. No. 60/398,384 filed Jul. 25, 2002, entitled “dispersion Strengthened Bond Coats for Thermal Barrier Coatings and related Method and System thereof” the entire disclosure of which is hereby incorporated by reference herein.

The present application is also related to International Application No. PCT/US02/28654, filed Sep. 10, 2002 entitled “Method and Apparatus for Application of Metallic Alloy Coatings,” of which is assigned to the present assignee and is hereby incorporated by reference herein in its entirety.

### GOVERNMENT SUPPORT

This invention was made with government support under the Office of Naval Research -N00014-00-1-0438. The government has certain rights in the invention.

### FIELD OF THE INVENTION

The present invention provides a method and an apparatus for efficiently applying a bond coat to a surface for thermal barrier coating systems using a directed vapor deposition (DVD) approach, and more particularly providing a dispersion strengthened bond coat that has an improved life expectancy by mitigating ill effects attributed to bond coat yield and creep. The dispersoids on the bondcoat surface can also be used to improve the adhesion of thermally grown oxides that are subsequently formed on the bondcoat.

### BACKGROUND OF THE INVENTION

Metallic alloy coatings are widely used to create functionality that is not possessed by the underlying material. A good example is the case of thermal barrier coating (TBC) systems which are used for the thermal and oxidation protection of the high temperature components used in advanced gas turbine and diesel engines to increase engine operating temperatures (and therefore improve engine efficiency) and to improve component durability and life. The TBC's currently in use are multi-layer systems consisting of a Zirconia based top layer that thermally protects an internally cooled, high temperature superalloy component, and an underlying bond coat applied to the super alloy to improve its adhesion to the top coat and reduce the rate of oxidation. The bond coat is typically an aluminum containing alloy such as MCrAlY (M=Ni and/or Co) or an aluminum based intermetallic such as a nickel aluminide containing varying amounts of Pt, and/or rare earth such Hf. When this layer is exposed to oxygen at high temperature it forms a well bonded, thin (˜1 μm) thermally grown (aluminum) oxide (TGO) layer which impedes further oxidation and hot corrosion of the underlying component. This TGO layer is formed on the surface of the aluminum-rich alloy bond coat layer by a chemical (oxidation) reaction. This reaction is not volume conserving. The oxide occupies a larger volume than the metal consumed. Significant stresses (up to ˜1G Pa) are therefore created when the oxide is constrained by the underlying metal. Additional stresses are created by thermal expansion mismatch between the TGO layer and the other materials in the system. If the bondcoat is insufficiently strong at the temperature of use to resist these stresses, the TGO layer rumples and eventually causes failure of the system (by spallation of the top coat). The strength of the bondcoat is governed by its composition and structure. Both are constrained by the methods used for its application.

Bond coats have conventionally been applied using a variety of techniques depending on the materials system used. For example MCrAlY bond coats are applied using low pressure plasma spray (LPPS), electron beam physical vapor deposition EB-PVD) and occasionally by sputtering. The aluminide bond coats are typically applied using a diffusion based process. Such processes include pack cementation, vapor phase aluminiding (VPA), or chemical vapor deposition (CVD). The diffusion processes result in a bond coat with two distinct zones; an outer zone which contains an oxidation resistant phase (such as beta-NiAl) and a diffusion zone which consists entirely of the oxidation resistant phase and secondary phases (such as gamma prime, gamma, carbides and sigma).

The primary function of the bond coat is to form a thin, slow growing, alpha alumina oxide layer (TGO) which protects the underlying component for oxidation and corrosion. This function is dependent on the composition and morphology of the coating. The composition is critical to the formation of the TGO layer for two reasons. The first is the need to have an aluminum level high enough to support the continued growth of the protective aluminum oxide layer during the lifetime of the coating system. As a TGO grows in service the aluminum content is continually decreased. When the aluminum content falls below a critical level, nonprotective oxides begin to form which lead to spallation of the TGO layer. Thus, a large aluminum reservoir is desired. TGO formation can also be effected by minor alloy additions which may occur as a result of inter-diffusion between and bond coat and the superalloy substrate. Such elements can increase the growth rate of the TGO layer and may promote the formation of unwanted, nonprotective oxide scales. It also provides a means for sulfur and other oxide interface embrittling elements to leach the TGO layer. Ideally, inter-diffusion between the bond coat and the superalloy should be limited both during the formation of the bond coat and during service of the component.

The surface morphology of a bond coat can also effect TGO growth. For example, a dense coating free of open porosity is required to form a protective scale on the coating surface. Open porosity results in internal oxidation of the bond coat and oxidation of the underlying component. Another key morphological feature of the bond coat is its grain size. The presence of insoluble particles has been used to create fine grain sizes (x) which are thought to increase the lifetime of TBC systems. Higher yield and creep strength bond coats are desired as they limit the thermomechanical phenomena which lead to failure of the TBC system. However, these can be difficult to achieve with current process technologies.

Bond coat strength can in part be retained by insulating the metallic component. The component and bond coat's temperature is then reduced, allowing it to last longer or to survive with less cooling air (cooling air reduces the performance of the engine). Recent work (See J. W. Hutchinson, M. Y. He, A. G. Evans, J. Mech. Phys. Solids, 48, 2000, pg 709, herein incorporated by reference) has identified bond coat rumpling as a contributor to spallation of the ceramic top coat. This occurs by creep of the bond coat resulting from stresses created during thermal cycling of the TGO/bond coat system. The typical bond coats are either aluminide (or platinum modified aluminide) or MCrAlY type coatings. These both contain a beta NiAl intermetallic phase, which is very weak at elevated temperatures. In addition to the work of J. W. Hutchinson et. al., earlier work (See Duderstadt U.S. Pat. No. 5,498,484 and Goldman et al. U.S. Pat. No. 5,712,050, of which are hereby incorporated by reference herein in their entirety) has suggested that strengthening the bond coats produces improved lives. This work was all performed with low pressure plasma spray (LPPS) processing. Strengthening by adding solid solution strengthening elements has been explored extensively. This approach is amenable to implementation by some of the process technologies in current use.

Work by Artz (See E. Arzt and P. Grable, Acta Mater., 46 (8), 1998, pp. 2717-2727, of which is hereby incorporated by reference herein in its entirety) has shown that Al₂O₃ dispersoids with sizes of 1-100 nm greatly increase NiAl's resistance to creep, FIG. 2. Wittenberger et al. (See Structural Intermetallics, Ed. J. D. Wittenberger, TMS, 1993, pp. 819-828, of which is hereby incorporated by reference herein in its entirety) have shown similar improvements using AlN dispersoids, FIG. 3. These dispersoids can be resistant to coarsening at the use temperature and therefore remain in a finely dispersed state. So called oxide dispersion strengthened (ODS) alloys are in widespread use.

The conventional processes currently in use for applying bond coats suffer severe limitations when used for depositing finely dispersed particles in a metal alloy bond coat. PVD processing has been used in the past to produce dispersoids for strengthening (by Movchan) in copper and other structural materials. Movchan's work primarily was performed with co-evaporation of an oxide to form the dispersoid. While reactive evaporation is widely used for some applications (ard coatings, optical and electronic primarily), its use to form stable dispersoids of controlled size, volume fraction, and interparticle spacing in bond coats for turbine airfoils has not been reported.

There is therefore a need in the art for a low cost deposition approach for applying bond coats which contain stable, 1-100 nm diameter dispersoids with volume fractions up to 10% in bond coats for turbine air foils or any component on which a coating system may be to protect the component from its environment. Such dispersoids mitigate the damage imparted on the components caused by yield and creep of the bond coat. Those at the surface of the bond coat can nucleate a preferred (corundum) aluminum oxide phase in the TGO layer. Further, there is a need in the art for a deposition approach for applying bond coats that enable the creation of a desirable dispersion and coating grain size in the deposited bond coat.

In all such cases, the ability to deposit compositionally controlled coatings efficiently, uniformly, at a high rate, with high part throughput, and in a cost-effective manner is desired. Some illustrative examples of deposition systems are provided in the following applications and patents and are co-assigned to the present assignee 1) U.S. Pat. No. 5,534,314, filed Aug. 31, 1994, entitled “Directed Vapor Deposition of Electron Beam Evaporant,” 2) U.S. Pat. No. 5,736,073, filed Jul. 8, 1996, entitled “Production of Nanometer Particles by Directed Vapor Deposition of Electron Beam Evaporant,” 3) U.S. Pat. No. 6,478,931, filed Aug. 7, 2000, entitled “Apparatus and Method for Intra-layer Modulation of the Material Deposition and Assist Beam and the Multilayer Structure Produced There from,” and corresponding Divisional U.S. application Ser. No. 10/246,018, filed Sep. 18, 2002, 4) International Application No. PCT/US01/16693, filed May 23, 2001 entitled “A process and Apparatus for Plasma Activated Deposition in a Vacuum,” and corresponding U.S. application Ser. No. 10/297,347, filed Nov. 11, 2002, and 5) International Application No. PCT/US02/13639, filed Apr. 30, 2002 entitled “Method and Apparatus for Efficient Application of Substrate Coating;” of which all of these patents and applications are hereby incorporated by reference herein in their entirety. The present invention discloses, among other things an apparatus and a method for applying a bond coating(s) on a substrate(s) in an improved and more efficient manner.

Other U.S. Patents that are hereby incorporated by reference herein in their entirety include the following:

U.S. Pat. No. 6,096,381, Zheng (2000)

U.S. Pat. No. 6,123,997, Schaeffer et al. (2000)

U.S. Pat. No. 6,153,313, Rigney et al. (2000)

U.S. Pat. No. 6,168,874, Gupta et al. (2001)

U.S. Pat. No. 6,255,001, Darolia (2001)

U.S. Pat. No. 6,258,467, Subramanian (2001)

U.S. Pat. No. 6,273,678, Darolia (2001)

U.S. Pat. No. 6,291,084, Darolia et al. (2001)

U.S. Pat. No. 6,306,524, Spitsberg et al. (2001)

U.S. Pat. No. 6,436,473 Darolia et al. (2002)

U.S. Pat. No. 6,455,167 Rigney et al. (2002)

U.S. Pat. No. 6,461,746 Darolia et al. (2002)

U.S. Pat. No. 6,485,845 Wustman et al. (2002)

U.S. Pat. No. 6,585,878 Stangman et al. (2003)

U.S. 2002/0110698 A1 Sing (2002)

### SUMMARY OF THE INVENTION

The present invention provides a method and an apparatus for efficiently applying a dispersion strengthened bond coating to a surface for thermal barrier coating systems using a directed vapor deposition (DVD) approach. To overcome the limitations incurred by conventional methods, the present invention uses a modified energetic beam directed vapor deposition (DVD) technique to evaporate and deposit compositionally and morphologically controlled bond coats at high rate. In one modality, the present invention DVD technique uses the combination of an energetic beam source (e.g., beam gun) (capable of processing material in a low vacuum environment) and a combined inert gas/reactive gas carrier jet of controlled composition to create engineering films. In this system, the vaporized material can be entrained in the carrier gas jet and deposited onto the substrate at a high rate and with a high materials utilization efficiency. The velocity and flux of the gas atoms entering the chamber, the nozzle parameters, and the operating chamber pressure can all be significantly varied, facilitating wide processing condition variation and allowing for improved control over the properties of the deposited layer. In particular, under some (higher pressure/evaporation rate) processing conditions, nanoscopic particles can be reactively formed in the vapor and incorporated in the cooling.

In another aspect of the present invention, by employing plasma enhancement, multisource crucibles and appropriate process condition control, the morphology, composition, dispersoid size and concentration, the bondcoat grain size and porosity of deposited layers are all controlled. In a second modality, the present invention uses a different evaporation source to reactively create dispersoids which are then entrained in the vapor plume used for depositing the coating. In a third modality, dispersoids are created before deposition and are entrained in the noble gas stream and used to transport the bond coat vapor to the component surface. In modalities one, two, and three a plasma may also be used to control the bond coat structure. In all modalities, the result is a low cost deposition approach for applying bond coats which can have compositions and dispersoids distributions which are difficult to deposit using other conventional approaches.

The DVD apparatus and method comprises a vacuum chamber, energetic beam source (e.g., beam gun), evaporation crucible(s), and inert/reactive gas jet. In addition, a plasma can be created. A substrate bias system capable of applying a DC or alternating potential to at least one of the substrates can then be used for plasma assisted deposition. The electron beam impinges on at least one of the vapor flux sources contained in the crucible. The resulting vapor is entrained in at least one of the carrier gas streams. Hollow cathode arc plasma activation source may or may not be used to ionize at least one of the generated vapor flux and at least one of the carrier gas stream. The ionized or non-ionized generated vapor flux and carrier gas stream are attracted to the substrate surface by allowing a self-bias of the ionized gas and vapor stream or the potential to pull the ionized stream to the substrate.

In an alternative embodiment an end-hall ion source is modified to function as the evaporation and plasma creating system. FIGS. 10(A)-(B) show a modified gridless ion source of the type described by Kaufman and Robinson (See Operation of Broad Beam Sources, by Harold R. Kaufman and Raymond S. Robinson, Commonwealth Scientific Corp., Alexandria, Va., pp 55-62, 1984). In the approach of the present invention a low voltage exterior electron beam is used to create a plasma in the throat of the evaporant source. The anode is axisymmetric with a central hole in which is fitted a water cooled crucible, which in turn contains one or a multiplicity of evaporation sources. FIG. 10(B) shows a cross section.

In other preferred embodiments, the DVD apparatus and method comprises a vacuum chamber having a radio frequency field that is used to ionize the evaporant and/or the carrier gas stream and a self and/or static or radio frequency bias voltage applied to the substrate that is used to provide plasma enhanced deposition of the coating.

In other preferred embodiments, the DVD apparatus and method comprises a technique for creating a plasma consisting of partially or fully ionized evaporant or carrier gas stream that is used in combination with a self or applied DC or RF bias voltage applied to the substrate to provide plasma enhanced deposition of a coating.

In a second embodiment, the present invention provides a method for applying at least one bond coating on at least one substrate for forming a thermal barrier system. The method-includes: presenting at least one substrate; forming a bond coat on at least a portion of at least one substrate by a directed vapor deposition (DVD) technique; reactively forming dispersoids in said bond coat; and depositing a thermal-insulating layer on the bond coat. In some embodiments the substrate is presented to the substrate in a chamber, wherein the chamber has an operating pressure ranging from about 0.1 to about 32,350 Pa. The method may further include: presenting at least two evaporant sources to the chamber(could be one source as well); presenting at least one carrier gas stream to the chamber; impinging said at least two evaporant sources with at least one electron energetic beam (or other energetic beam types) in the chamber to generate an evaporated vapor flux in a main direction respective for any of the two evaporant sources impinged by the electron beam; and deflecting at least one of the generated evaporated vapor flux by at least one of the carrier gas stream, wherein the carrier gas stream is essentially parallel to the main direction and substantially surrounds the evaporated flux, wherein the evaporated vapor flux at least partially coats at least one substrate to form said bond coat, or any other coating or thin film.

In a third embodiment, the present invention provides an apparatus for applying at least one bond coating on at least one substrate for forming a thermal barrier system. The apparatus includes a chamber, wherein the chamber has an operating pressure ranging from about 0.1 to about 32,350 Pa, wherein at least one of the substrates is presented in the chamber. The apparatus further comprises: at least two evaporant sources (could be one source as well) disposed in the chamber; at least one carrier gas stream provided in the chamber; and an electron energetic beam system (or other energetic beam system) providing at least one electron beam (or other energetic beam). The electron beam (or other energetic beam) impinges said at least two evaporant sources with at least one electron beam (or other energetic beam type) in the chamber to generate an evaporated vapor flux and deflects at least one of generated evaporated vapor flux by at least one of carrier gas stream, wherein the evaporated vapor flux at least partially coats at least one of the substrates to form a bond coat and reactively forms dispersoids in said bond coat.

In a fourth embodiment, the present invention provides component having a thermal barrier coating system on a substrate thereof, the thermal barrier coating system includes a bond coat deposited on at least a portion of the substrate by a directed vapor deposition (DVD) technique, wherein said bond coat comprises dispersoids in said bond coat; and a thermal-insulating layer overlying at least a portion of the bond coat. The component may be produced by the present invention methods discussed throughout this document. The advantages of the present invention include, but are not limited to: improved use of expensive gases, increased deposition efficiency, and improved uniformity in the coating,

The result is a dramatically improved method for the efficient application of a bond coating to a surface for thermal barrier systems wherein the bond coat(s) has an improved life expectancy and performance due to the mitigation of yield and creep effects.

These and other objects, along with advantages and features of the invention enclosed herein, will be made more apparent from the description, drawings, and claims that follow.

### DESCRIPTION OF THE FIGURES

The foregoing and other objects, features, and advantages of the present invention, as well as the invention itself, will be more fully understood from the following description of preferred embodiments, when read together with the accompanying drawings, in which:

FIG. 1 is a schematic illustration of a partial view of the substrate showing a thermal barrier coating system on the substrate in accordance with an embodiment of this invention.

FIG. 2 is a graphical depiction of the effect of aluminum oxide dispersoids that produce the beneficial effects. At 1500K, the stress required to cause a 10⁻⁴ s⁻¹ strain rate that must be increased from 15 to 60 MPa in a fully recrystallized NiAl alloy containing aluminum oxide dispersoids.

FIG. 3 is a graphical depiction the effects of aluminum nitrides that produce the desired effect. The stress that is required to cause a creep strain rate of 10-5s-1 must be increased from 29 MPa when no AlN dispersoids are present to 90-Mpa when 5 Vol % AlN is present in a NiAl intermetallic.

FIG. 4 is a schematic illustration of the directed vapor deposition (DVD) processing system. Included in the process are the ability to evaporate from two or more individual source materials and, optionally, the ability to ionize the evaporated flux using hollow cathode plasma activation. Optionally, may be evaporated by one source.

FIG. 5 is a schematic illustration showing the use of a two crucible arrangement for alloy deposition using conventional electron beam evaporation.

FIG. 6 is a schematic illustration of the present invention showing the use of multiple source evaporation in directed vapor deposition. For example, using a 100 kHz scan rate, a single e-beam can be scanned across multiple, closely-spaced vapor sources for precise alloy or multilayer deposition. The water-cooled copper crucible and independent source feed motors make possible independent material feed and evaporation. The setup is shown schematically for Ni/Y/Al/Pt evaporation.

FIG. 7 is a schematic illustration of the hollow cathode plasma activation unit, optionally, used in the present invention DVD apparatus. The cathode plasma activation device emits low energy electrons that ionize the vapor atoms and carrier gas. By properly biasing the substrate the impact energy of both species can be controlled.

FIG. 8 provides an enlarged partial view of the embodiment shown in FIG. 7.

FIG. 9 shows a schematic representation of an alternative embodiment of the present invention, demonstrating the deflection of the main gas and vapor stream and a compensation of it by of an opposed gas injection from the anode.

FIGS. 10(A)-(B) show a schematic representation of a modified gridless ion source processing system, providing a partial elevation view and partial cross-sectional view, respectively.

### DESCRIPTION OF THE PREFERRED EMBODIMENTS

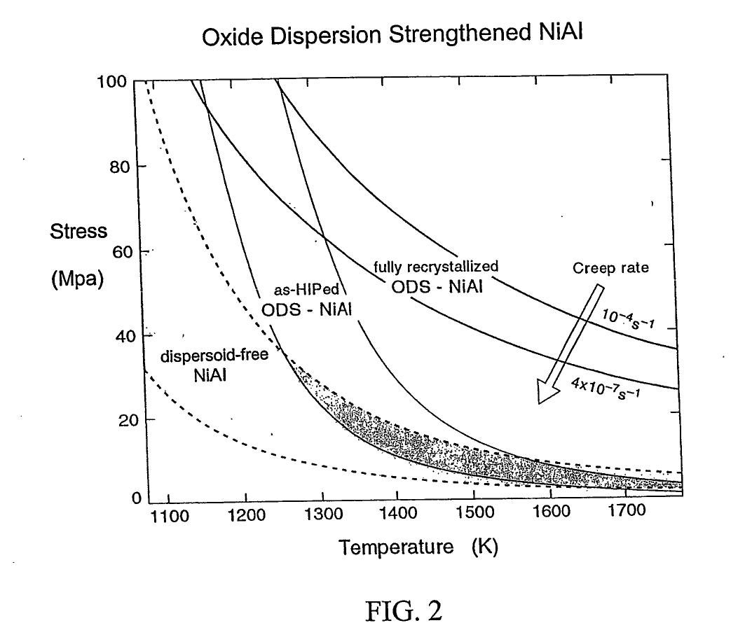

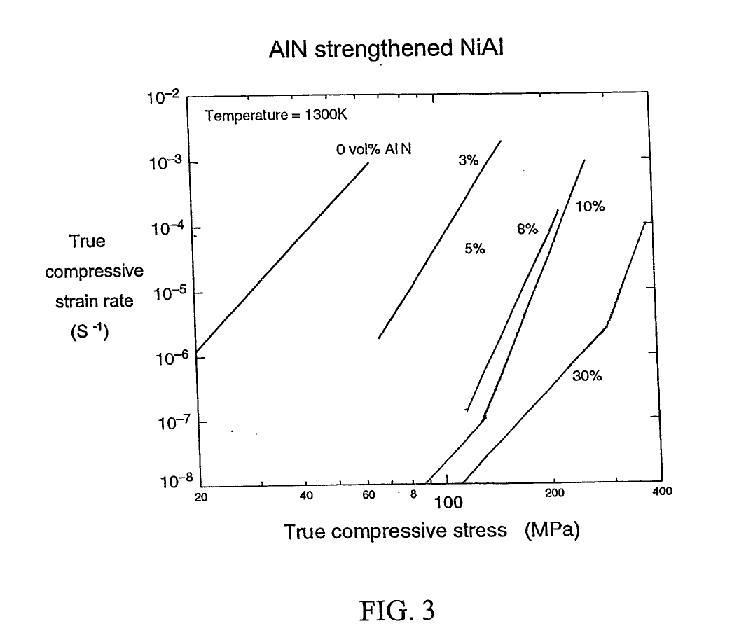

The present invention is an improved thermal barrier coating (and related method and system for making) which comprises, among other things, a) a substrate typically a nickel base superalloy, b) a dispersion strengthened bond coat and c) a ceramic insulating layer or layers on top. The dispersion strengthened bond coat in this invention is novel in that, but not limited thereto, it produces improved coating system life due to greater yield and creep strength. It may also improve the adhesion of the TGO layer to the bondcoat and enable top coats of preferred morphology to be nucleated. The bond coat consists of one or more metallic or intermetallic phases with a dispersoid of about 1-100 nanometer diameter particles throughout. The volume fraction of the dispersoid is at least about 0.5% but can be varied from about <0.1 to about >10%. The preferred compositions for the metallic or intermetallic portion are 1) Ni—50 atom % Al, 2) 50 atom% Ni+Pt—50 atom % Al. Additions of Cr, and oxygen active elements (such as Hf, Y, Zr, La, and other rare earth elements) can also be made. Addition of the oxygen active elements to non-dispersion strengthened coatings has been used to increase oxidation resistance, See FIG. 2. Here these elements may also help to form particularly stable dispersoids (rather than aluminum oxide or nitride).

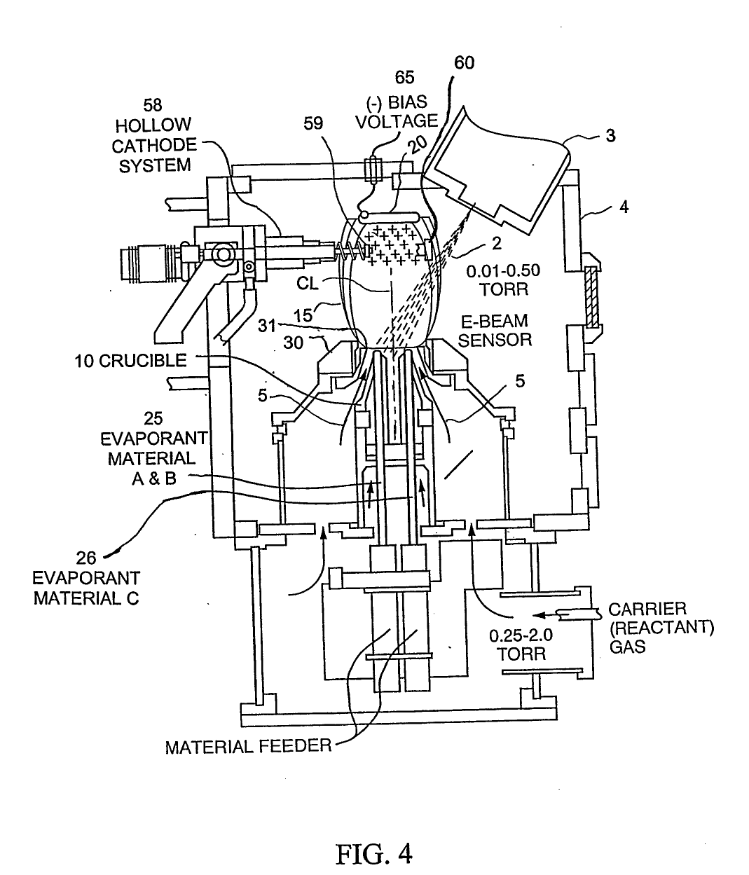

A process and system to produce these new bond coats is also invented. The process uses EB-PVD to form the coating either by reaction between the evaporant and with a reactive gas present in the coating chamber (See FIG. 4), or by the addition of the dispersoids to the noble gas stream created in the system or externally. The reactive gas will react with the desired species (aluminum or one or more of the oxygen active elements described above) in the gas phase to get the microstructure necessary to produce an effective coating. By reacting in the gas phase a finer, dispersed oxide, carbide, boride, oxycarbide, nitride, Carbonitride, Nitrocarbide, or Carbooxide or other suitable dispersant can be formed. Other suitable dispersoids would include, but not limited thereto, as follows:

a) MX whereby M=Mn, Cr, Fe, Ni, Sc, Hf, Ti, V, Zr, Al, Nb, Ta, Si, or W, or combinations thereof and X=oxide, carbide, boride, oxycarbide, nitride, Carbonitride, Nitrocarbide, Carbooxide;

b) ZrO₂, Y₂O₃, Cr₂O₃, Al₂O₃-3 (13, 20, 40, or 50)TiO₂, TiO₂, Cr₂O₃—TiO₂—SiO₂, ZrO₂-8(13)Y₂O₃, ZrO₂-5(10)CaO, SiNC, SiCₓN_{y} (x+y=4), (Al,Fe)₂O₃, AlN, or AlY;

c) SiC, Si₃N₄, SiCₓO₄₋ₓ, BC_{y}O_{3-y}, SiNC, SiOC, TiN, Ti₂AlN, TiAl₃, TiB₂, AlB₂, or WC;

d) carbide, nitride, carbonitride, or boride of a 4b-, 5b-, or 6b group transition metal;

e) nitride, boride, or oxide of M; and/or

f) at least one kind of carbide, nitride, carbonitride, and boride of Fe, Co, or Ni.

The typical EB-PVD process used for bond coats is not capable of the gas phase reaction since it operates at very low pressure (typically a pressure of less than 0.01 Pa). Furthermore, a method to energize the evaporative species and the reactive gas is necessary. Breaking the bonds of the reactive gas to make monotomic oxygen or nitrogen helps to drive the reaction in the gas phase as well. The DVD process has been used to make initial coatings. The present invention DVD process may operate at pressures of about 1.0 to about 10 Pa (but may also operate at a range of about 0.1 to about 32,350 Pa). At these higher pressures the number of atomic collisions in the gas phase is much higher than typical EB-PVD processing allowing for more reaction to occur. Also, use of a hollow cathode to inject electrons or other means of creating a plasma which will energize and ionize the vapor species will help to cause the reactions to proceed. Furthermore, biasing the substrate relative to the plasma created by the hollow cathode will drive the ionized species to the substrate with a high energy. This has the added benefit of producing a denser coating that will have better properties.

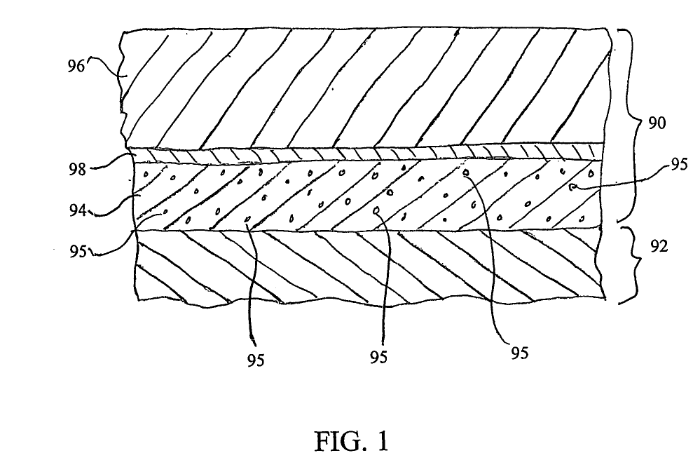

Turning to FIG. 1, FIG. 1 schematically represents a TBC system 90 of a type that benefits from the teachings of this invention. As shown, the coating system 90 includes a ceramic layer 96 bonded to the substrate 92 with an overlay bond coat 94 having ceramic dispersoids 95 of an oxygen compound dispersed at least substantially throughout. To attain the dispersoids the ceramic is reactively created during the deposition process. The substrate 92 (e.g., blade, etc.) is preferably a high-temperature material, such as an iron, nickel or cobalt-base superalloy. To attain a strain-tolerant columnar grain structure, the ceramic layer 96 is deposited by the desired deposition technique. A preferred material for the ceramic layer 96 is an yttria-stabilized zirconia (YSZ), with a suitable composition being about 4 to about 20 weight percent yttria, though other ceramic materials could be used, such as yttria, nonstabilized zirconia, or zirconia stabilized by ceria (CeO₂), scandia (SC₂ O₃) or other oxides. The ceramic layer 96 is deposited to a thickness that is sufficient to provide the required thermal protection for the underlying substrate 92, generally on the order of about 125 to about 300 micrometers. The surface of the bond coat 94 oxidizes to form an aluminum oxide surface layer (alumina scale) 98 to which the ceramic layer 96 chemically bonds.

The present invention directed vapor deposition (DVD) apparatus and related method provide the technical basis for a small volume, low cost coating process capable of depositing the bond coat of a thermal barrier coating (TBC) system. DVD technology utilizes a trans-sonic gas stream to direct and transport a thermally evaporated vapor cloud to a component. The footprint of the vapor plume can be varied from a diameter of about 2-3 cm to as much about 20 cm or more. As a result small airfoils, or portions of large airfoils (that are being repaired) can be coated with very little overspill and thus waste of the vapor cloud. Typical operating pressures are approximately in the about 6.67 to about 66.7 Pa (but may also operate at a range of about 0.1 to about 32,350 Pa) range requiring the use of inexpensive mechanical pumping. In this new process, material is thermally vaporized using a high voltage/low power (about 60 or 70 kV/10 KW) axial e-beam gun (modified to function in a low vacuum environment). The vapor is then entrained in a carrier gas stream and deposited onto a substrate at high rate (about >10 μm min⁻¹ for a plume cross sectional area of about 50 cm²) and with a high materials utilization efficiency greater than ten times that of conventional EB-PVD processes. These characteristics combine to make the present invention DVD process a low cost solution for depositing bond coats onto gas turbine airfoils and other engine components. Moreover, the bond coat deposition creates ceramic dispersoids that help prevent creep and other cracking of the substrate and coatings.

FIG. 4 shows a schematic illustration of the directed vapor deposition process. Using this process, dense nickel aluminide bond coats that are desired for TBC applications have been produced. In DVD, the carrier gas stream 5 is created by a rarefied, inert gas supersonic expansion through a nozzle 30. The speed and flux of the atoms entering the chamber 4, the nozzle parameters, and the operating chamber pressure can all be varied leading to a wide range of accessible processing conditions. Critical to the process is the supersonic carrier gas stream maintained by achieving a high upstream pressure (i.e. the gas pressure prior to its entrance into the processing chamber), Pᵤ, and a lower chamber pressure, Pₒ. The ratio of the upstream to downstream pressure along with the size and shape of the nozzle opening 31 controls the speed of the gas entering the chamber 4. The carrier gas molecular weight (compared to that of the vapor) and the carrier gas speed controls its effectiveness in redirecting the vapor atoms via binary collisions towards the substrate 20. As will be discussed later, alternative embodiments of the present invention process will provide other capabilities to evaporate from two or more individual source rods and the ability to ionize the evaporated flux using hollow cathode plasma activation.

Still referring to FIG. 4, the aforementioned DVD process is schematically shown in FIG. 4, improving the deposition efficiency, increasing the deposition rate, providing coating dispersoids, and enhancing the coating uniformity. As will be discussed later, the hollow cathode system 58 is optional based on desired operations. In a preferred embodiment, the carrier gas 5 is realigned so that it is substantially in-line with the crucible 10. In this alignment, the carrier gas flow is placed completely or substantially around the crucible 10 so that the vapor flux 15 no longer has to be turned 90 degrees towards the substrate 20, but rather can be simply focused onto the substrate located directly above the evaporant source 25 for material A and R and evaporant source 26 for material C. Material A, B and/or C may include Y, Al, Ni, Pt, Co, Mo, Fe, Zr, Hf, Yb, and/or other reactive elements that form the matrix of the bond coat and the ceramic dispersoids throughout the bond coat. The carrier gas 5 flows substantially parallel with the normal axis, identified as CL. Additionally, as will be discussed later herein, the nozzle 30 has a nozzle gap or opening 32, through which the carrier gas 5 flows, is designed such that a more optimal carrier gas speed distribution for focusing the vapor 15 is produced. Also shown is-the energetic beam source 3, such as electron beam source, laser source, heat source, ion bombardment source, highly focused incoherent light source, microwave, radio frequency, EMT, or combination thereof, or any energetic beams that break chemical bonds and vacuum chamber 4.

Regarding component heating, TBC's are typically applied at a very high temperature (e.g., 1050° C.). This temperature is achieved by pre-heating the blade before it is entered into the chamber. Due to the configuration of the system in the present invention, such that the blade is placed directly above the source and the carrier gas flow rate may be decreased, the amount for radiant heat from the source is greatly increased and thus blade heating using a standard pre-heating furnace may be realized.

Moreover, in the existing design of the conventional DVD system, both the vapor and carrier gas flow pass through supersonic shock waves as the gas and vapor move away from the gas flow nozzle. These shock waves affect the density and distribution of the vapor. When a coating surface is then placed such that it intersects the flow, the resulting atomic structure of growing film can be affected by the distance from the gas flow nozzle to the coating surface (relative to the shocks in the flow). In the present invention system, there will still be supersonic shock waves in the carrier gas flows emerging from the ring nozzle. However, since the vapor is no longer incorporated directly into that carrier gas flow, its distribution and density will be less affected by the shocks in the system. As a result, the present invention process will become less critically dependent upon the position of gas flow nozzle and coating surface. Thus, when the geometry of the part being coated dictates a smaller (or larger) source to substrate separation, the present invention system design will be able to more easily accommodate such parts while still producing the desired atomic structure.

Another advantage of present invention nozzle design is that it may be used with larger source sizes without the need for adding significantly more pumping capacity. The pumping capacity required for DVD is a function of the nozzle opening area. Larger openings require more pumping capacity in order to reach the same chamber pressure than smaller openings. Additionally, as the source size is increased, the nozzle opening size must be increased, and this is true for both configurations. However, the area increase for the present invention ring configuration is much less than for the conventional circular shaped opening. For example, if one assumes that increasing the source size from 0.0127 m to 0.0381 m requires a three fold increase in the nozzle diameter, the increased nozzle opening area can be calculated for both configurations. It is found that the circular opening would have a nine fold increase in area while the ring opening would have only a 2.76 fold increase. Thus, a significant savings in the required pumping capacity and gas flow costs is achieved. The benefit of increasing the source size is that the vapor emitting surface would be increased by nine fold, and in conjunction with the 3 to 4 time improvement in the deposition efficiency, could lead to a deposition rate which is more than 30 times higher than current DVD technology (i.e., greater than 500 μm/min. is then possible based on current deposition rates (of 15 to 20 μm/min.)).

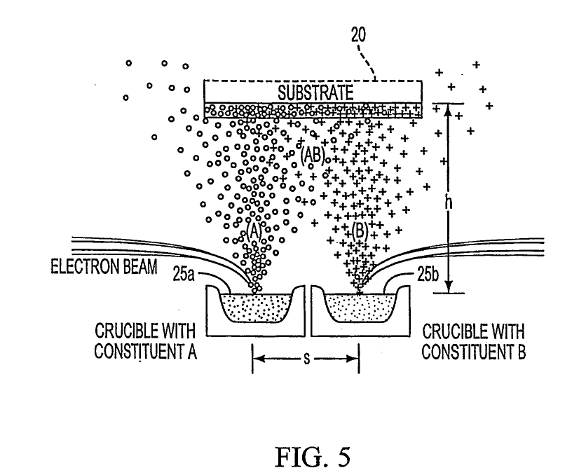

Turning to FIG. 5, an exemplary illustration is shown wherein materials are evaporated from two or more sources using either a single or multiple electron beam gun arrangement. As shown in FIG. 5, in a conventional EB-PVD configuration, the film composition is strongly dependent on the position of the sources and the substrate position. The compositional uniformity and region of vapor mixing can be maximized when the source spacing, s, is small and the source to substrate distance, h, is large. However, such a configuration is often not advantageous as large source to substrate distances lower the materials utilization efficiency (MUE, the ratio of evaporated atoms which deposit onto the substrate) and the use of a small source size leads to reduced evaporation rates. This is not conducive to high rate deposition and is significantly more costly than single source evaporation. Improved multisource deposition approaches are therefore desired which yield compositionally uniform vapor fluxes and a high process efficiency are therefore desired.

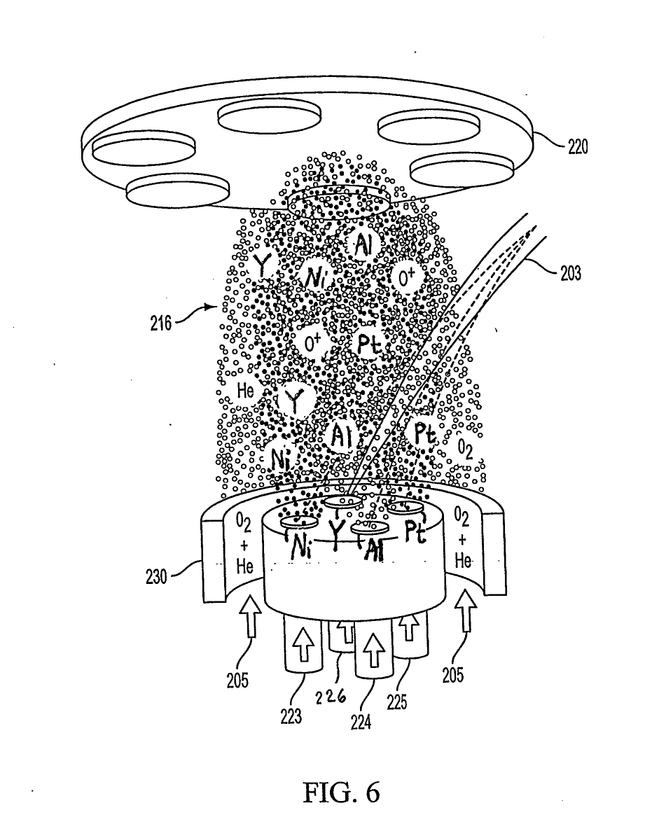

As another aspect of the present invention, as illustrated in FIG. 6, there is provided an alternative embodiment, wherein vapor phase mixing can be achieved by aligning two (or potentially more) sources 223, 224, 225, 226 (evaporant materials A, B, & C) in line with a carrier gas flow 205 and using electron beam scanning 203 to uniformly heat both (or plurality of) sources (optionally, may be achieved with one evaporant source). The use of the carrier gas jet in this embodiment not only scatters the vapor flux toward the substrate, leading to a potentially high MUE (and high deposition rates), but also randomizes the vapor trajectory facilitating vapor phase mixing of the two (or plurality of) fluxes 216. A high MUE would allow for the use of small diameter metal source materials, which could be spaced closely together to further improve the compositional uniformity of the coating, while still achieving a high rate of deposition. The composition of the deposited layer could be systematically controlled by altering the electron beam scan pattern to change the surface temperature (and thus the evaporation rate) of each source material.

In one embodiment, the electron beam gun in the directed vapor deposition system has been equipped with a high speed e-beam scanning system (up to about 100 kHz) with a small beam spot size (<about 0.5 mm) to allow multiple crucibles to be placed in close proximity to one another for precise heating and vapor mixing. The carrier gas surrounds the vapor sources and allows the vapor from the neighboring melt pools to interdiffuse. The composition of the deposited layer can then be controlled by altering the electron beam scan pattern to change the temperature (and thus the evaporation rate) of each source material. In effect this is a splitting of the beam into two or more beams (if two or more sources) with precisely controllable power densities. As a result, the present invention DVD system enables the evaporation of several materials simultaneously and thus, precise composition control in the coating can be achieved. Using a 100 kHz scan rate, a single e-beam can be scanned across multiple, closely-spaced vapor sources for precise alloy or multilayer deposition. The water-cooled copper crucible and independent source feed motors make possible independent material feed and evaporation. The setup is shown schematically for Ni/Y/Al/Pt evaporation. A single e-beam can be scanned across multiple, closely-spaced vapor sources for precise alloy or multilayer deposition. The water-cooled copper crucible and independent source feed motors make possible independent material feed and evaporation

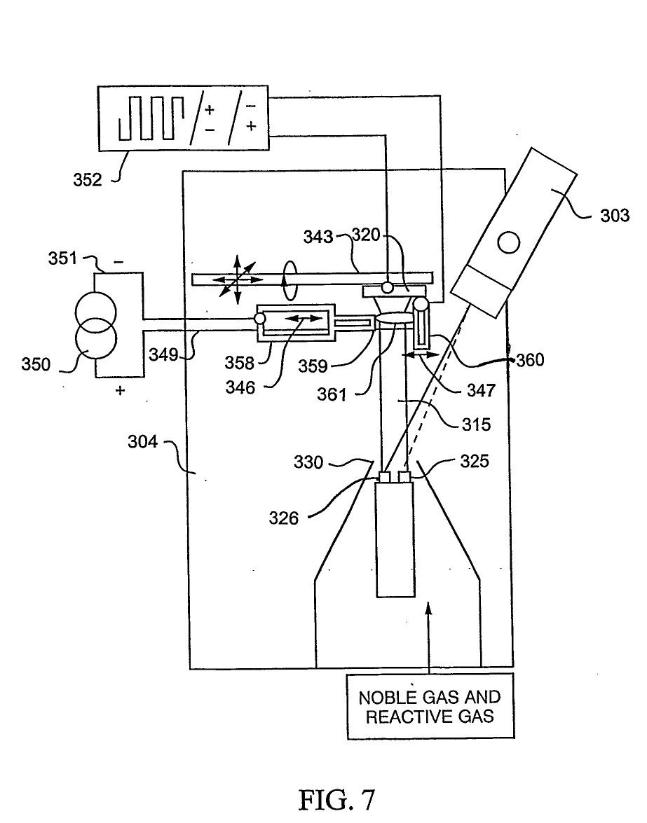

In an alternative embodiment, to endow the DVD process with the ability to create dense, crystalline coatings, a plasma activation unit is incorporated into the DVD system. As will be discussed in greater detail below, plasma-activation in DVD is performed by a hollow-cathode plasma unit capable of producing a high-density plasma in the system's gas and vapor stream, See FIGS. 7-9. The particular hollow cathode arc plasma technology used in DVD is able to ionize a large percentage of all gas and vapor species in the mixed stream flowing towards the coating surface. This ionization percentage in a low vacuum environment is unique to the DVD system. The plasma generates ions which can be accelerated towards the coating surface by either a self-bias or by an applied electrical potential. Increasing the velocity (and thus the kinetic energy) of ion by using an applied potential allows the energy of depositing atoms to be varied, affecting the atomic structure of coatings. The DVD process has the ability to combine focused evaporation with plasma activation for rapid, efficient deposition of various crystal structures. The plasma device emits low energy electrons which ionize the vapor atoms and carrier gas. By properly biasing the substrate the impact energy the both species can be controlled.

Turning to FIG. 7, the major components of the present invention DVD system including a hollow cathode arc plasma activation and substrate bias supply as schematically shown. The present invention DVD system is comprises a vacuum chamber 304, a first rod feed evaporator 325 (evaporant A & B) and second rod evaporator 326 (evaporant C) that are placed and heated up to evaporation temperature of evaporant by the electron-beam of an electron gun 303 and provides the vapor for coating of substrates 320. Vaporized evaporant is entrained in the supersonic gas and vapor stream 315 formed by the nozzle 330. The substrate(s) 320 are fixed at a substrate holder 343 which enables shift of the substrate in any independent direction and to be swiveled. For example, the translation motion in the horizontal plan allows the exposed surface areas of the substrate to the vapor stream for defined dwelling times and control of the local coating thickness. The vertical motion can be used to keep constant the distance between plasma and surface for curved substrates. Swivel motion, in coordination with the translation motions, can be used to enable the coating of complete three-dimensional parts or can be used also to change the incidence angle of the vapor particles in the course of layer coating in a defined way for getting distinct layer properties. The hollow cathode (arc source) 358 is placed laterally below substrate holder 343 with a short distance between the cathode orifice 359 and the gas and vapor stream 315. The anode 360 is arranged opposite the cathode orifice 359 (i.e., on an approximate distant side of the stream 315) so that the fast electrons and the plasma discharge 361 crosses the gas and vapor stream 315. The fixtures for the cathode 346 and for the anode 347 provides the ability to adjust the distance of the cathode 358 and the anode 360, thereby influencing the diameter and the shape of gas and vapor stream 315.

The plasma discharge 361 is in close proximity (arranged with short distance) to the surface of the substrate 320 enabling close contact between dense plasma and the substrate surface to be coated. In the vicinity of the evaporation electron-beam from the electron gun 303,.the anode power line 349 from the power generator 350 to the anode 360 is arranged closely and in parallel with both the plasma discharge 359 and the cathode power line 351, which runs from the cathode to the power generator 350. Between the substrate 320 and the anode 360, a bias generator 352 is applied that allows for generation of a positive, a negative or a periodically alternating voltage between the substrate 320 and the plasma 361.

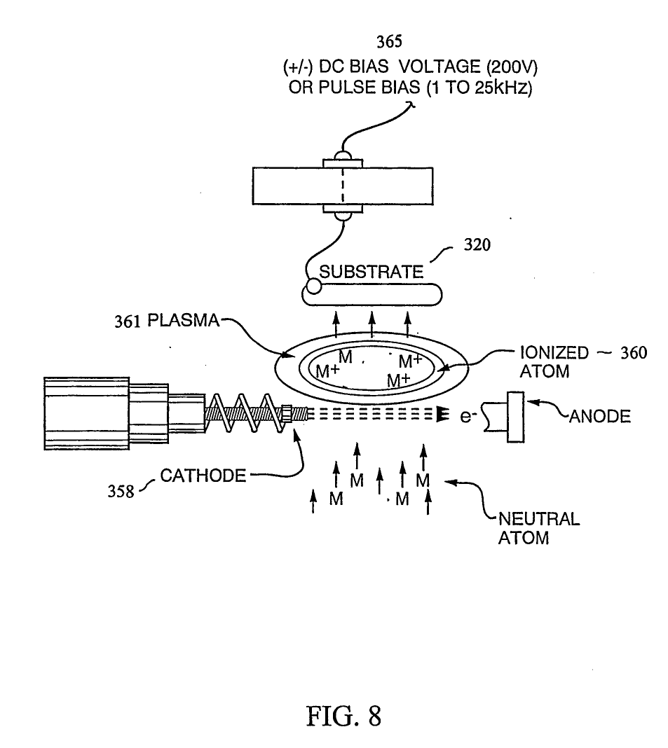

FIG. 8 provides an enlarged partial view of the embodiment shown in FIG. 7.

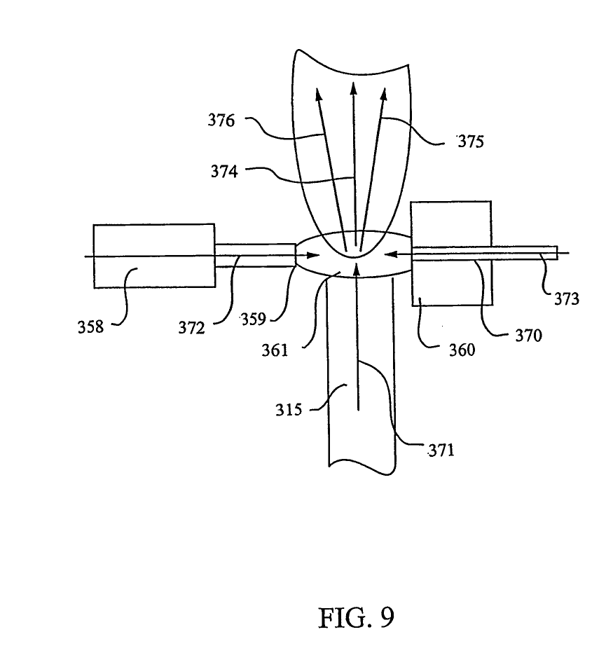

Turning to FIG. 9, FIG. 9 schematically illustrates an alternative embodiment wherein the instant system and method has the main gas and vapor stream 315 which is deflected from the vertical direction 371 by interaction with the working gas flow 372 of the hollow cathode 358 escaping from the cathode orifice 359 resulting in a bending of the vapor stream 375 away from the cathode side. The directed gas injection 373 is in an opposed position to the cathode through a gas channel 370 integrated in the anode block 10 and enables the compensation of deflection. Therefore, the resulting gas and vapor stream 374 flows in the vertical direction again. Overcompensation will result in a bending of the main gas and vapor stream 376 towards the cathode side. The same channel 370 can be used for clear gas influx to keep free the anode or parts of the anode surface from insulating contamination. This clear gas influx feature can been done independently or in combination with the bending effect injection of the anode.

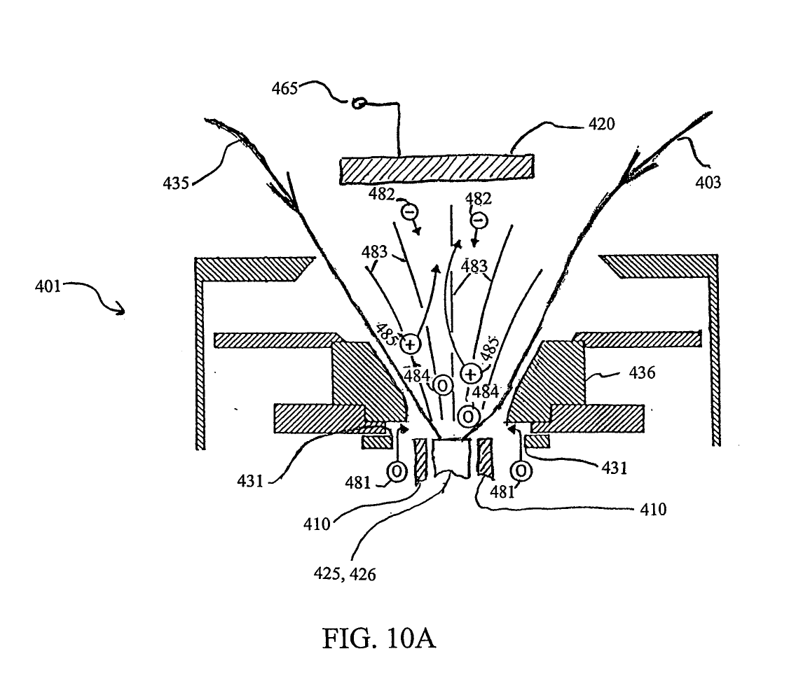

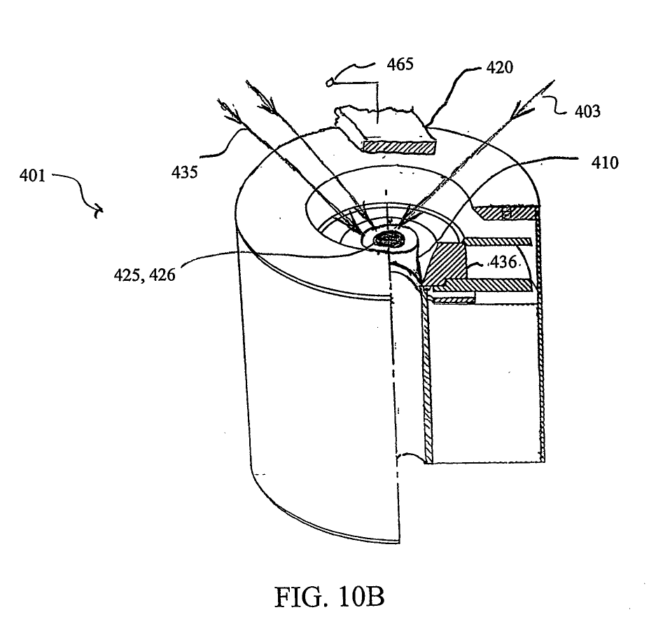

Other means for creating a plasma made up of the ionized evaporant and/or carrier gas atoms can be utilized including the use of microwave or other radio frequency discharges. Once created, plasma enhanced deposition is possible under the action of a self bias or one applied externally to the substrate. The applied bias can be static (DC) or oscillated (RF) or pulsed. Referring to FIGS. 10(A)-(B), in an alternative embodiment an end-hall ion source is modified to function as the evaporation and plasma creating system 401. FIGS. 10(A)-(B) shows a modified gridless ion source of the type described by Kaufman and Robinson (See Operation of Broad Beam Sources, by Harold R Kaufman and Raymond S. Robinson, Commonwealth Scientific Corp., Alexandria, Va., pp 55-62, 1984, hereby incorporated by reference herein in its entirety). In the present invention approach a low voltage exterior electron beam 435 or source is used to create a plasma in the throat of the evaporation source(s) 425, 426. The anode 436 is axisymmetric with a central hole in which is fitted a water cooled crucible, which in turn contains one or a multiplicity of evaporation sources 425, 426.

Still referring to FIGS. 10(A)-(B), a brief description of source operation is presented whereby typical operating sequences and procedures are described. The various processes that occur in a modified end-Hall ion source 401. The neutral atoms or molecules 481 of the working gas are introduced to the ion source through a port 431, such as He gas jet. Electrons 482 created from the low voltage electron source approximately follow magnetic field lines 483 back to the discharge region enclosed by the anode 436 and strike atoms or molecules 484 therein. Some of these collisions produce ions 485. The mixture of electrons and ions in the discharge region forms a conductive gas, or plasma. Because the density of the neutral atoms or molecules falls off rapidly downstream of the anode 436 (toward the substrate/target 420) most of the ionizing collisions with neutrals occur in the region surrounded by the anode 436.

In conclusion, the present invention describes a series of steps, and an apparatus for use therewith for applying a bond coating to a substrate of a thermal barrier coating system using an electron beam directed vapor deposition technique, and more particularly providing a dispersion strengthened bond coat that has an improved life expectancy by mitigating ill effects attributed to yield and creep.

Some advantages of the present invention process and apparatus, but not limited thereto is that it provides for the materials utilization efficiency of the process to be improved, deposition rate increased, coating uniformity improved, stable ceramic dispersoids in bond coats for greater yield and creep strength, multiple blade coating during each coating cycle, and carrier gas flow costs optimized.

In addition, the present invention provides for alloy strengthening in high temperature metallic alloys that can be melt or solid state processed to materials that one applied by vapor deposition. The creep strengthened coating contains nanoscopic particles of oxides, nitrides, borides, carbides, and other materials which are formed by reactive codeposition. The present invention method, system, and resultant structure may be utilized for, but not limited thereto, high temperature coatings, e.g. for protecting rocket gas turbine, or diesel engine components.

Finally, an advantage of the present invention method, system, and resultant structure is that it, but not limited thereto, greatly increased coating lifetime (about 2-10 times greater) resulting from elimination of coating spallation by the “rumpling” mechanism.

The invention may be embodied in other specific forms without departing from the spirit or essential characteristics thereof. The foregoing embodiments are therefore to be considered in all respects illustrative rather than limiting of the invention described herein. Scope of the invention is thus indicated by the appended claims rather than by the foregoing description, and all changes which come within the meaning and range of equivalency of the claims are therefore intended to be embraced herein.

1. A method for forming a thermal barrier coating system, the method comprising the steps of:
presenting at least one substrate;
forming a bond coat on at least a portion of at least one said substrate by a directed vapor deposition (DVD) technique;
reactively forming dispersoids in said bond coat; and
depositing a thermal-insulating layer on said bond coat.

2. The method of claim 1, wherein said dispersoids comprise an oxygen compound.

3. The method of claim 1, wherein said dispersoids comprise at least one of Oxide, Carbide, Boride, Nitride, Oxycarbide, Carbonitride, Carbonoxide, Mn, Cr, Fe, Ni, Sc, Hf, Ti, V, Zr, Al, Nb, Ta, Si, or W, or combination thereof.

4. The method of claim 1, wherein said DVD techinique comprises:
said presenting of at least one of said substrate includes presenting said substrate to a chamber, wherein said chamber has an operating pressure ranging from about 0.1 to about 32,350 Pa,;
presenting at least one evaporant source to said chamber;
presenting at least one carrier gas stream to said chamber;
impinging said at least one said evaporant source with at least one energetic beam in said chamber to generate an evaporated vapor flux in a main direction respective for any of said evaporant sources impinged by said electron beam; and
deflecting at least one of said generated evaporated vapor flux by at least one of said carrier gas stream, wherein said carrier gas stream is essentially parallel to the main direction and substantially surrounds said evaporated flux, wherein said evaporated vapor flux at least partially coats at least one said substrate to form said bond coat.

5. The method of claim 4, wherein said energetic beam comprises at least one of electron beam source, laser source, heat source, ion bombardment source, highly focused incoherent light source, microwave, radio frequency, EMN, or any energetic beam that break chemical bonds, or combination thereof.

6. The method of claim 4, further comprising:
said chamber further includes a substrate bias system capable of applying a DC or alternating potential to at least one of said substrates;
impinging said at least one of said generated vapor flux and at least one of said carrier gas stream with a working gas generated by at least one hollow cathode arc plasma activation source to ionize said at least one of said generated vapor flux and at least one of said carrier gas stream; and
attracting said ionized generated vapor flux and said carrier gas stream to a substrate surface by allowing a self-bias of said ionized gas and vapor stream or said potential to pull the ionized stream to said substrate.

7. The method of claim 6, said generated electrons from said hollow cathode source is regulated for direction through variations in the quantity of working gas passing through said hollow cathode source.

8. The process of claim 6, wherein the distance between said cathode source and said generated evaporated vapor flux is regulated for ionization of the entire generated evaporated vapor flux.

9. The method of claim 4, further comprising at least one nozzle, wherein said at least one carrier gas stream is generated from said at least one nozzle and said at least one evaporant source is disposed in said at least one nozzle, wherein said at least one said nozzle comprises:
at least one nozzle gap wherein said at least one said carrier gas flows there from; and
at least one evaporant retainer for retaining at least one said evaporant source, said evaporant retainer being at least substantially surrounded by at least one said nozzle gap.

10. The method claim 9, wherein said evaporant retainer is a crucible.

11. The method of claim 4, further comprising:
said chamber further includes a substrate bias system capable of applying a DC or alternating potential to at least one of said substrates;
impinging said at least one of said generated vapor flux and at least one of said carrier gas stream with a low energy beam to ionize said at least one of said generated vapor flux and at least one of said carrier gas stream; and
attracting said ionized generated vapor flux and said carrier gas stream to a substrate surface by allowing a self-bias of said ionized gas and vapor stream or said potential to pull the ionized stream to said substrate.

12. The method of claim 4, wherein at least one of said at least one evaporant source is a material selected from the group consisting: NiY, NiAl, PtAl, PtY, Ni, Y, Al, Pt, NiAlPt, NiYPt, NiPt, Co, Mo, Fe, Zr, Hf, Yb, and other reactive elements.

13. The method of claim 4, wherein at least one of said at least one evaporant sources is made from alloys formed of one or more of a material selected from the group consisting: NiY, NiAl, PtAl, Pty, Ni, Y, Al, Pt, NiAlPt, NiYPt, NiPt, Co, Mo, Fe, Zr, Hf, Yb, and other reactive elements.

14. A method for forming a thermal barrier coating system, the method comprising the steps of:
presenting at least one substrate;
forming a bond coat on at least a portion of at least one said substrate by a directed vapor deposition (DVD) technique;
providing nanoclusters under a pressure greater than said chamber pressure; and
injection said nanoclusters at a high velocity into the said chamber, thereby resulting in dispersoids impinged in said bond coat.

15. The method of claim 14, further comprising:
depositing a thermal-insulating layer on said bond coat.

16. A directed vapor deposition (DVD) apparatus for forming a thermal barrier coating system, the apparatus comprising:
a chamber, wherein said chamber has an operating pressure ranging from about 0.1 to about 32,350 Pa, wherein at least one substrate is presented in said chamber;
at least one evaporant source disposed in said chamber;
at least one carrier gas stream provided in said chamber; and
an energetic beam system providing at least one energetic beam, said energetic beam:
impinging at least one said evaporant source with at least one said energetic beam in said chamber to generate an evaporated vapor flux; and
deflecting at least one of said generated evaporated vapor flux by at least one of said carrier gas stream, wherein said evaporated vapor flux at least partially coats at least one of said substrates to form a bond coat and reactively forms dispersoids in said bond coat.

17. The method of claim 16, wherein said dispersoids comprise an oxygen compound.

18. The method of claim 16, wherein said dispersoids comprise at least one of Oxide, Carbide, Boride, Nitride, Oxycarbide, Carbonitride, Carbonoxide, Mn, Cr, Fe, Ni, Sc, Hf, Ti, V, Zr, Al, Nb, Ta, Si, or W, or combination thereof.

19. The apparatus of claim 16, further comprising:
said energetic beam system providing at least one energetic beam, said energetic beam:
impinging at least one of said evaporant source with at least one said energetic beam in said chamber to generate an evaporated vapor flux; and
deflecting at least one of said generated evaporated vapor flux by at least one of said carrier gas stream, wherein said evaporated vapor flux at least partially coats at least one of said substrates to form a thermal-insulating layer on said bond coat with said dispersoids therein.

20. The method of claim 16, wherein said energetic beam comprises at least one of electron beam source, electron gun source, laser source, heat source, ion bombardment source, highly focused incoherent light source, microwave, radio frequency, EMF, or any energetic beam system that breaks chemical bonds, or combination thereof.

21. The apparatus of claim 16, wherein:
said generated evaporated vapor flux is in a main direction respective for any of said evaporant sources impinged by said energetic beam; and
wherein said carrier gas stream is essentially parallel to the main direction and substantially surrounds said generated evaporated flux.

22. The apparatus of claim 16, further comprising:
a substrate bias system capable of applying a DC or alternating potential to at least one of said substrates;
at least one hollow cathode arc source generating a low voltage beam, said at least one hollow cathode arc source:
impinging said at least one of said generated vapor flux and at least one of said carrier gas stream with a working gas generated by at least one said hollow cathode arc plasma activation source to ionize said at least one of said generated vapor flux and at least one of said carrier gas stream; and
attracting said ionized generated vapor flux and said carrier gas stream to a substrate surface by allowing a self-bias of said ionized gas and vapor stream or said potential to pull the ionized stream to said substrate.

23. The apparatus of claim 22, wherein said hollow cathode arc source comprises at least one cathode orifice wherein a predetermined selection of said cathode orifices are arranged in close proximity to the gas and vapor stream; and
an anode is arranged opposite of said cathode source wherein the gas and vapor stream is there between said cathode source and said anode.

24. The apparatus of claim 16, further comprising at least one nozzle, wherein said at least one carrier gas stream is generated from said at least one nozzle and said at least one evaporant source is disposed in said at least one nozzle, wherein said at least one said nozzle comprises:
at least one nozzle gap wherein said at least one said carrier gas flows there from; and
at least one evaporant retainer for retaining at least one said evaporant source, said evaporant retainer being at least substantially surrounded by at least one said nozzle gap.

25. The apparatus of claim 24, wherein said evaporant retainer is a crucible.

26. The apparatus of claim 16, further comprising:
a substrate bias system capable of applying a DC or alternating potential to at least one of said substrates;
at least one low energy beam source for generating a low voltage beam, said at least one low energy beam source:
impinging said at least one of said generated vapor flux and at least one of said carrier gas stream with a low energy beam to ionize said at least one of said generated vapor flux and at least one of said carrier gas stream; and
attracting said ionized generated vapor flux and said carrier gas stream to a substrate surface by allowing a self-bias of said ionized gas and vapor stream or said potential to pull the ionized stream to said substrate.

27. A component having a thermal barrier coating system on a substrate thereof, the thermal barrier coating system comprising:
a bond coat deposited on at least a portion of said substrate by a directed vapor deposition (DVD) technique, wherein said bond coat comprises dispersoids in said bond coat.

28. The component of claim 27, further comprising:
a thermal-insulating layer overlying at least a portion of said bond coat.

29. The component of claim 27, wherein said component is produced by the method of claim 2.

30. The component of claim 27, wherein said component is at least one of: gas turbine engine component, diesel engine component, turbine blade, and airfoil.
